(19) United States
(12) Patent Application Publication
(10) Pub. No.: US 2026/0067631 A1
(43) Pub. Date: Mar. 5, 2026

(54) REALISTIC ACOUSTIC AUDIO OUTPUT DEVICE FOR INTERCOMMUNICATION

(71) Applicant: Raon A&C Inc., Daejeon (KR)

(72) Inventors: Youn Soo CHO, Daejeon (KR); Dong Sun SHIN, Daejeon (KR); Ji Yeon KIM, Daejeon (KR); Deuk KI NAM, Daejeon (KR); Ji Yeon LEE, Daejeon (KR)

(73) Assignee: Raon A&C Inc., Daejeon (KR)

(21) Appl. No.: 19/101,632

(22) PCT Filed: Apr. 13, 2023
(86) PCT No.: PCT/KR2023/004973

§ 371 Date: Feb. 6, 2025

(30) Foreign Application Priority Data
Dec. 6, 2022 (KR) 10-2022-0168381

(51) Int. Cl. H04S 7/00; G06F 3/16; H03G 5/16

(52) U.S. Cl. CPC H04S 7/305; G06F 3/165; H03G 5/165; H04S 2420/01

(57) ABSTRACT

Proposed is a realistic sound audio output device for an intercommunication system, which includes a noise reduction unit for reducing ambient noise when a plurality of audio signals are inputted, a multi-sound source determination unit for outputting the plurality of stereo signals after determining whether a plurality of processed audio signals transmitted through the noise reduction unit are stereo sound sources, a multi-audio rendering unit composed of an audio channel separation rendering unit for performing a first sound image localization reflecting sound source location information with respect to the plurality of stereo signals or an audio panorama rendering unit for performing a second sound image localization reflecting the sound source location information and tracking information, and a sound source output processing unit for post-processing and outputting the plurality of stereo signals through the multi-audio rendering unit.

### TECHNICAL FIELD

The present disclosure relates to a realistic acoustic audio output device for intercommunication, which enables listening to realistic sounds in a stereo listening environment through applying a sense of spatiality to each channel through dual sound image localization, by reducing ambient noise in a noise reduction unit when a plurality of audio signals are inputted, by outputting a plurality of stereo signals in a multi-sound source determination unit after determining whether a plurality of processed audio signals transmitted are stereo sound sources, by performing a first sound image localization reflecting sound source location information or a second sound image localization reflecting the sound source location information and tracking information with respect to a plurality of outputted stereo signals in a multi-audio rendering unit, and by post-processing and outputting in a sound source output processing unit.

### BACKGROUND ART

As is well known, an intercom system, which is an intercommunication system (ICS, hereinafter referred to as “intercom”), is a multiplex communication system that mixes each signal channel inputted for each communication target, such as a microphone and the like, into a stereo channel or mono channel to output, that is used to provide communication for commands or contact between a broadcasting studio and a control room or between control rooms, that provides communication for commands or contact between an aircraft and a control station or between aircraft, and that is applied and utilized in various multi-channel communication fields, such as internal communications of fighter jets and trams.

However, inputted multi-channel sound sources are simply mixed and outputted in the conventional intercom, thereby causing a problem of reducing speech intelligibility and perception rate of situational judgment, and in the case of intercoms in fighter jets and trams, danger signals with respect to surrounding risk factors are expressed and transmitted in sound to the listener, but there is a demand to express in sound the location and movement information on the risk factors in order to judge dangerous situation since it is difficult to grasp situations on the direction and movement with regard to the risk factors before using additional equipment such as radar.

In order to solve the problem described above, there is a demand for the development of an audio output device capable of realistically outputting various inputted sounds.

### DOCUMENT OF RELATED ART

[Patent Document 1]

1. Korean Patent No. 10-0542129 (registered on Jan. 3, 2006)

### DISCLOSURE

### Technical Problem

The present disclosure is to provide a realistic acoustic audio output device for intercommunication, which enables listening to realistic sounds in a stereo listening environment through applying a sense of spatiality to each channel through h sound image localization, by reducing ambient noise in a noise reduction unit when a plurality of audio signals are inputted, by outputting a plurality of stereo signals in a multi-sound source determination unit after determining whether a plurality of processed audio signals transmitted are stereo sound sources, by performing a first sound image localization reflecting sound source location information or a second sound image localization reflecting the sound source location information and tracking information with respect to a plurality of outputted stereo signals in a multi-audio rendering unit, and by post-processing and outputting in a sound source output processing unit.

The objectives of the exemplary embodiments of the present disclosure are not limited to the objectives mentioned above, and other objectives not mentioned will be clearly understood by those skilled in the art to which the present disclosure belongs from the following description.

### Technical Solution

According to an exemplary embodiment of the present disclosure, a realistic acoustic audio output device for intercommunication is provided that includes a noise reduction unit for reducing ambient noise when a plurality of audio signals are inputted, a multi-sound source determination unit for outputting the plurality of stereo signals after determining whether a plurality of processed audio signals transmitted through the noise reduction unit are stereo sound sources, a multi-audio rendering unit composed of an audio channel separation rendering unit for performing a first sound image localization reflecting sound source location information with respect to the plurality of stereo signals or an audio panorama rendering unit for performing a second sound image localization reflecting the sound source location information and tracking information, and a sound source output processing unit for post-processing and outputting the plurality of stereo signals through the multi-audio rendering unit.

In addition, according to an exemplary embodiment of the present disclosure, a realistic acoustic audio output device for intercommunication is provided where the audio channel separation rendering unit includes a first preprocessing unit for performing preprocessing in order to prevent distortion of a sound source with respect to the plurality of stereo signals, a 1-1st reverberation processing unit for selectively processing reverberation on the plurality of preprocessed stereo signals for a sense of spatiality of the sound source, a first ear boost unit for adjusting the plurality of stereo signals subjected to a reverberation processing to a preset listening volume value, a first sound source location information provision unit for providing a first sound source location information by using a head-related transfer function (HRTF), a first sound image localization unit for performing the first sound image localization on the plurality of stereo signals adjusted to the preset listening volume value by reflecting the first sound source location information, and a 1-2nd reverberation processing unit for selectively processing reverberation for the sense of spatiality of the sound source on the plurality of stereo signals on which the first sound image localization is performed.

In addition, according to an exemplary embodiment of the present disclosure, a realistic acoustic audio output device for intercommunication is provided where the first sound image localization unit includes an elevation pinna filter unit for processing a pinna effect depending on an elevation position of a sound image with respect to the plurality of stereo signals, an azimuth pinna filter unit for expressing a location depending on a direction angle on a horizontal plane with respect to the plurality of stereo signals, and a head shadow filter unit for processing an effect depending on a human head shape with respect to the plurality of stereo signals outputted from the elevation pinna filter unit and the azimuth pinna filter unit.

In addition, according to an exemplary embodiment of the present disclosure, a realistic acoustic audio output device for intercommunication is provided where the audio panorama rendering unit includes a second preprocessing unit for performing preprocessing in order to prevent distortion of a sound source with respect to the plurality of stereo signals, a 2-1st reverberation processing unit for selectively processing reverberation on the plurality of preprocessed stereo signals for a sense of spatiality of the sound source, a second ear boost unit for adjusting the plurality of stereo signals subjected to a reverberation processing to a preset listening volume value, a second sound source location information provision unit for providing a second sound source location information by using the head-related transfer function (HRTF), a tracking information processing unit for providing head movement information, a second sound image localization unit for performing the second sound image localization on the plurality of stereo signals adjusted to the preset listening volume value by reflecting the second sound source location information and the head movement information, and a 2-2nd reverberation processing unit for selectively processing reverberation for the sense of spatiality of the sound source on the plurality of stereo signals on which the second sound image localization is performed.

In addition, according to an exemplary embodiment of the present disclosure, a realistic acoustic audio output device for intercommunication is provided where the second sound image localization unit includes an elevation pinna filter unit for processing a pinna effect depending on an elevation position of a sound image with respect to the plurality of stereo signals, an azimuth pinna filter unit for expressing a location depending on a direction angle on a horizontal plane with respect to the plurality of stereo signals, and a head shadow filter unit for processing an effect depending on a human head shape for the plurality of stereo signals outputted from the elevation pinna filter unit and the azimuth pinna filter unit.

In addition, according to an exemplary embodiment of the present disclosure, a realistic acoustic audio output device for intercommunication is provided where the sound source output processing unit includes a volume normalizing unit for adjusting a volume difference with respect to the plurality of stereo signals outputted through the multi-audio rendering unit, a downmixing unit for downmixing the plurality of stereo signals outputted through the volume normalizing unit in response to the number of channels, and an equalizer processing unit for performing an equalizer adjustment on the plurality of stereo signals outputted through the downmixing unit and outputting the same.

### Advantageous Effects

The present disclosure can enable listening to realistic sounds in a stereo listening environment through applying a sense of spatiality to each channel through dual sound image localization, by reducing ambient noise in a noise reduction unit when a plurality of audio signals are inputted, by outputting a plurality of stereo signals in a multi-sound source determination unit after determining whether a plurality of processed audio signals transmitted are stereo sound sources, by performing a first sound image localization reflecting sound source location information or a second sound image localization reflecting the sound source location information and tracking information with respect to a plurality of outputted stereo signals in a multi-audio rendering unit, and by post-processing and outputting in a sound source output processing unit.

In addition, present the disclosure can improve communication performance by solving the phenomenon of reducing the intelligibility of audio signals where sounds are mixed and outputted when a plurality of audio signals are simultaneously uttered.

### DESCRIPTION OF DRAWINGS

FIG. 1 is a configuration diagram of a realistic acoustic audio output device for intercommunication according to an exemplary embodiment of the present disclosure,

FIGS. 2 and 3 are detailed configuration diagrams of an audio channel separation rendering unit provided in a realistic acoustic audio output device for intercommunication according to an exemplary embodiment of the present disclosure,

FIGS. 4 and 5 are detailed configuration diagrams of an audio panorama rendering unit provided in a realistic acoustic audio output device for intercommunication according to an exemplary embodiment of the present disclosure,

FIG. 6 is a detailed configuration diagram of a sound source output processing unit provided in a realistic acoustic audio output device for intercommunication according to an exemplary embodiment of the present disclosure,

FIG. 7 is a view showing a system to which a realistic acoustic audio output device for intercommunication according to an exemplary embodiment of the present disclosure is applied.

### MODE FOR INVENTION

The advantages and features of exemplary embodiments of the present disclosure and methods for achieving them will become clear with reference to exemplary embodiments described below in detail with the accompanying drawings. However, the present disclosure may not be limited to the exemplary embodiments disclosed below and may be implemented in various different forms, and the present exemplary embodiments may be provided to merely make the disclosure of the invention complete and to fully inform those skilled in the art, to which the present disclosure pertains, of the scope of the present disclosure and the present disclosure may be only defined by the scope of the claims. Throughout the specification, the same reference numerals may refer to the same components.

When it is determined that a detailed description of a known function or configuration may unnecessarily obscure the gist of the present disclosure in describing the exemplary embodiments of the present disclosure, the detailed description thereof will be omitted. Also, the terms to be described below may be terms defined in consideration of functions in the exemplary embodiments of the present disclosure, and may vary depending on the intention or custom of a user or an operator. Therefore, the definition should be based on the content throughout the present specification.

Hereinafter, exemplary embodiments of the present disclosure will be described in detail with reference to the accompanying drawings.

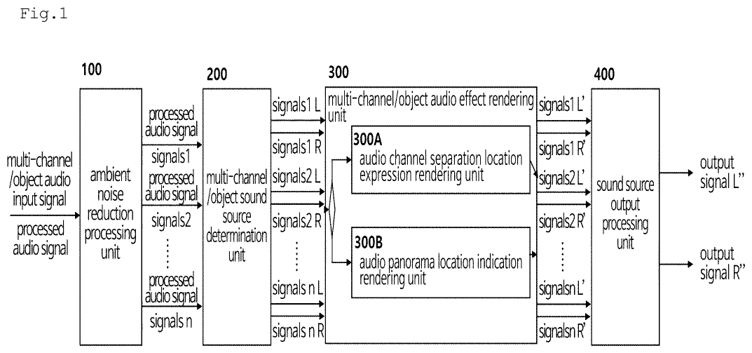

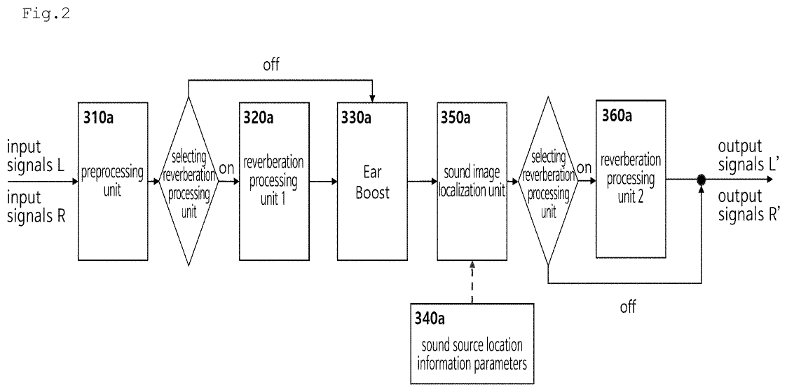

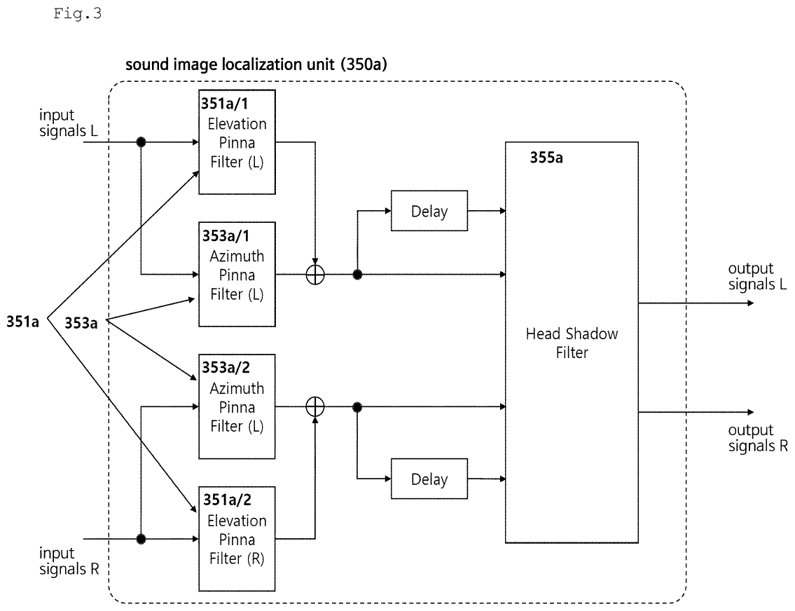

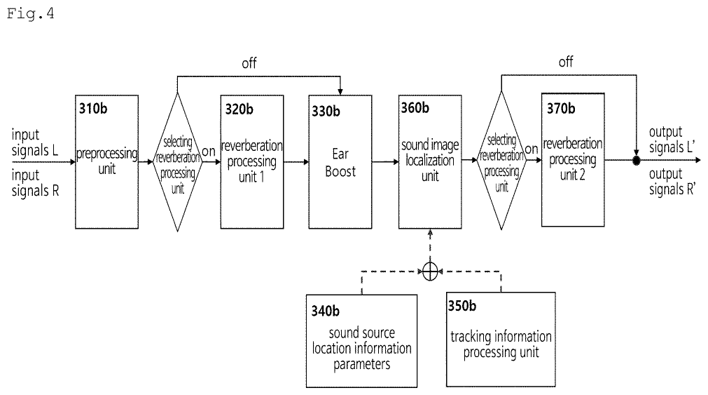

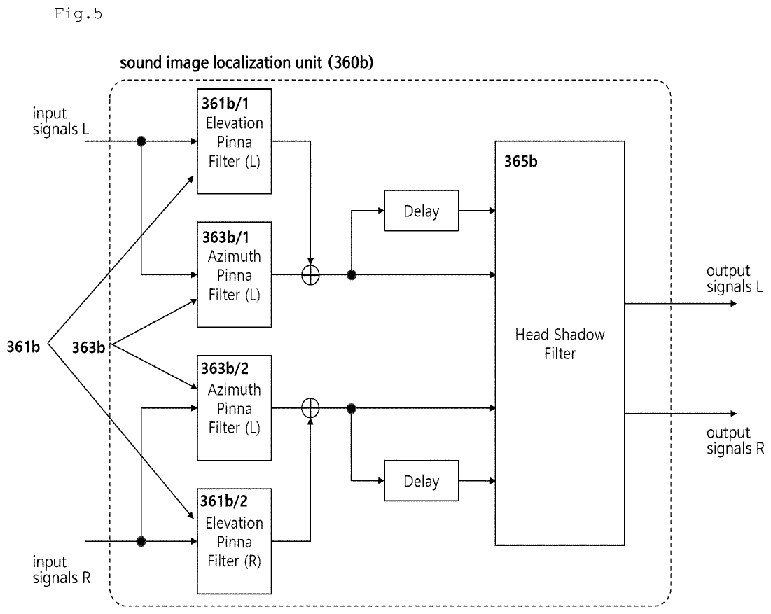

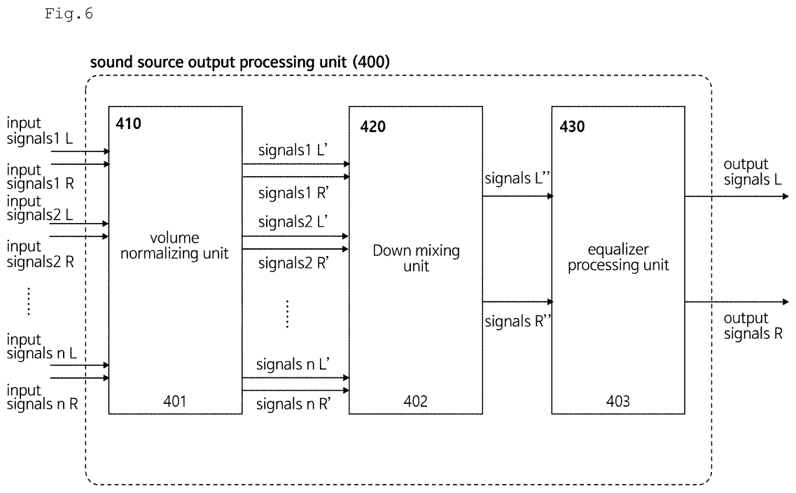

FIG. 1 is a configuration diagram of a realistic acoustic audio output device for intercommunication according to an exemplary embodiment of the present disclosure, FIGS. 2 and 3 are detailed configuration diagrams of an audio channel separation rendering unit provided in a realistic acoustic audio output device for intercommunication according to an exemplary embodiment of the present disclosure, FIGS. 4 and 5 are detailed configuration diagrams of an audio panorama rendering unit provided in a realistic acoustic audio output device for intercommunication according to an exemplary embodiment of the present disclosure, FIG. 6 is a detailed configuration diagram of a sound source output processing unit provided in a realistic acoustic audio output device for intercommunication according to an exemplary embodiment of the present disclosure.

Referring to FIGS. 1 to 6, the realistic acoustic audio output device for intercommunication according to an exemplary embodiment of the present disclosure may include a noise reduction unit 100, a multi-sound source determination unit 200, a multi-audio rendering unit 300, a sound source output processing unit 400, and the like.

The noise reduction unit 100 may reduce ambient noise when a plurality of audio signals are inputted and, for example, may be capable of reducing noise in audio signals inputted for multi-channels and multi-objects by using active noise control (ANC), active noise reduction (ANR), electronic noise canceling (ENC), and the like with respect to various external noise included in a plurality of audio signals such as multi-channel and multi-object performance venues, broadcasting stations, aircraft, trams, vehicles and the like, and with respect to noises generated in communication lines and be capable of outputting a plurality of processed audio signals to the multi-sound source determination unit 200.

In addition, the noise reduction unit 100 may detect speech sections through real-time speech modeling, and may be capable of reducing noise so that sound distortion can be minimized even at low SNR (signal to noise rate), and capable of effectively reducing noise not only for wideband speech but also for microphone noise of portable terminals by supporting not only the 8 kHz band targeting narrow band speech but also 16, 22.5, 24.32, and 1.48 kHz formats.

The multi-sound source determination unit 200 may determine whether a plurality of processed audio signals transmitted through the noise reduction unit 100 are stereo sound sources to output as the plurality of stereo signals, and the plurality of processed audio signals outputted through the noise reduction unit 100 may be outputted in a mono format or a stereo format, but since the corresponding sound source should be processed as a stereo signal in order to localize the phase of the sound source, after checking information of each processed audio signal, the stereo signal can be outputted to the multi-audio rendering unit 300 as it is, and a mono signal can be outputted to the multi-audio rendering unit 300 after the conversion of upmixing to a stereo signal.

The multi-audio rendering unit 300 may perform a first sound image localization reflecting sound source location information on the plurality of stereo signals, or perform a second sound image location reflecting the sound source location information and tracking information, and may include an audio channel separation rendering unit 300A or an audio panorama rendering unit 300B as shown in FIG. 1. Herein, a plurality of inputted stereo signals may be inputted to the audio channel separation rendering unit 300A or the audio panorama rendering unit 300B.

Herein, the sound coming toward the front of the face may have little difference in sound pressure transmitted to both ears, but the sound coming toward the side may have the head shadow effect in which the left and right have a difference of about 1/1000 second, such that the direction of the sound source can be recognized, and when the direction of the sound source cannot be distinguished by the head shadow effect, the tone can be distinguished according to the shape of the auricle, which is called the pinna effect.

The audio channel separation rendering unit 300A as described may perform the first sound image localization for the audio channel separation by reflecting the sound source location information on the plurality of stereo signals, and may include a first preprocessing unit 310a, a 1-1st reverberation processing unit 320a, a first ear boost unit 330a, a first sound source location provision unit 340a, a first sound image localization unit 350a, and a 1-2nd reverberation processing unit 360a, and the like as shown in FIG. 2.

Herein, the first preprocessing unit 310a may perform preprocessing in order to prevent distortion of the sound source for the plurality of stereo signals, and may perform the preprocessing to supplement distortion of the speech part during sound image localization according to the characteristics of the intercommunication system.

The 1-1st reverberation processing unit 320a may selectively perform reverberation processing on the plurality of preprocessed stereo signals for a sense of spatiality of the sound source, and selectively perform the reverberation processing of the sound source to allow the sound source to have the sense of spatiality in the case of the sound source requiring the sense of spatiality.

To elaborate on this reverberation processing, the reason why sound in reality is heard with the sense of spatiality is due to a combination of the sound heard directly and the sound reflected from walls and the like, and the reverberation technology can be implemented as a result of reflection, absorption, and diffusion of sound from each wall of the space surrounding the listener, and can be applied as a combination of the reflection group by generating an early reflection sound in the 1-1st reverberation processing unit 320a and then generating a late reflection sound in the 1-2nd reverberation processing unit 360a to be described later.

When the processing of the reverberation 1-1st reverberation processing unit 320a as described above is not required, the plurality of stereo signals outputted from the first preprocessing unit 310a may be inputted to the first ear boost unit 330a.

The first ear boost unit 330a may adjust the plurality of stereo signals subjected to the reverberation processing to a preset listening volume value, and may adjust the sound source having a low or high volume to a preset listening volume value to output so that the user can hear it.

The first sound source location information provision unit 340a may provide the first sound source location information by using a head-related transfer function (HRTF), and the head-related transfer function (HRTF) may be a transfer function that expresses an acoustic system from a sound located at a specific point in three-dimensional space to both ears of a person, containing the influence of diffraction and insulation due to the head and shoulders, and reflection and diffraction due to the outer ear (pinna) depending on the three-dimensional location of the sound source so that it can be recognized how a person perceives the location of the sound source in three dimensions, and may be affected by the size of the head and the location and shape of the outer ear.

The first sound image localization unit 350a may perform the first sound image localization by reflecting the first sound source location information on the plurality of stereo signals adjusted to a preset listening volume value, and may perform the first sound image localization for determining the location of the sound image by reflecting the first sound source location information provided by using the head-related transfer function (HRTF).

The 1-2nd reverberation processing unit 360a may selectively perform reverberation processing on the plurality of stereo signals where the first sound image localization is performed, for a sense of spatiality of the sound source and additional reverberation processing of the sound source may be selectively performed to enable the sound source to have the sense of spatiality in the case of the sound source requiring the sense of additional spatiality.

When the reverberation processing of the 1-2nd reverberation processing unit 360a as described above is not required, the plurality of stereo signals where the first sound image localization is performed through the first sound image localization unit 350a may be outputted to the sound source output processing unit 400.

As described above, the first sound image localization unit 350a may include a first elevation pinna filter unit 351a, a first azimuth pinna filter unit 353a, a first head shadow filter unit 355a, and the like, as shown in FIG. 3.

Herein, the first elevation pinna filter unit 351a may process a pinna effect by the elevation position of the sound image for the plurality of stereo signals, and may process and output the elevation position of the sound image by applying an elevation pinna filter where the pinna effect is applied.

Such a first elevation pinna filter unit 351a may include a 1-1st elevation pinna filter 351a/1 where a left input signal L is inputted and a 1-2nd elevation pinna filter 351a/2 where a right input signal R is inputted, and may process the elevation position of the sound image for each of the left input signal and the right input signal of the stereo signals.

The first azimuth pinna filter unit 353a may process a pinna effect by a direction angular position of the sound image for the plurality of stereo signals, and may process and output the direction angular effect of the sound image by applying an azimuth pinna filter where the pinna effect is applied.

Such a first azimuth pinna filter unit 353a may include a 1-1st azimuth pinna filter 353a/1 where a left input signal L is inputted and a 1-2nd azimuth pinna filter 353a/2 where a right input signal R is inputted, and may process the direction angular effect of the sound image for each of the left input signal and the right input signal of the stereo signals.

Herein, the left input signal L of the stereo signal may be inputted to a first head shadow filter unit 355a by processing the elevation position and direction angular effect of the sound image through the 1-1st elevation pinna filter 351a/1 and the 1-1st azimuth pinna filter 353a/1, and the right input signal R of the stereo signal may be inputted to the first head shadow filter unit 355a by processing the elevation position and direction angular effect of the sound image through the 1-2nd elevation pinna filter 351a/2 and the 1-2nd azimuth pinna filter 353a/2. Herein, a delay circuit may be provided so that the left input signal L and the right input signal R may be inputted to the first head shadow filter unit 355a at the same time.

The first head shadow filter unit 355a may process an effect by the human head shape with respect to the plurality of stereo signals outputted from the first elevation pinna filter unit 351a and the first azimuth pinna filter unit 353a, and may process and output a difference of the sound image caused by the human head so that sound sources in the left and right directions can be recognized, by applying the head shadow filter developed by modeling a head-related impulse response (HRIR) curve, which is obtained by measuring the difference in distance between ears and the effect by the human head shape according to the direction of sounds by using the head shadow effect.

When the filters provided in the first sound image localization unit 350a as described above are applied, realistic sounds having a sense of distance and direction may be outputted and heard even when using headphones or earphones.

In addition, the first sound image localization unit 350a as described above may process sound image localization in real time to fit the changing location and distance values for each of eight or more multi-channels and multi-objects, by implementing with a IIR (infinite impulse response) filter through lowering the order of each filter to 1st or 2nd order in order to minimize the amount of computation and memory usage so that portable terminals and the like can be applied.

Meanwhile, the audio panorama rendering unit 300B may perform the second sound image localization for the audio panorama processing by reflecting the sound source location information and tracking information on the plurality of stereo signals, and may include a second preprocessing unit 310b, a 2-1st reverberation processing unit 320b, a second ear boost unit 330b, a second sound source location information provision unit 340b, a tracking information processing unit 350b, a second sound image localization unit 360b, a 2-2nd reverberation processing unit 370b, and the like as shown in FIG. 4.

Herein, the second preprocessing unit 310b may perform preprocessing in order to prevent distortion of the sound source for the plurality of stereo signals, and may perform the preprocessing to supplement distortion of the speech part during sound image localization according to the characteristics of the intercommunication system.

The 2-1st reverberation processing unit 320b may selectively perform reverberation processing on the plurality of preprocessed stereo signals for a sense of spatiality of the sound source, and selectively perform the reverberation processing of the sound source to allow the sound source to have the sense of spatiality in the case of the sound source requiring the sense of spatiality.

When the reverberation processing of the 2-1st reverberation processing unit 320b as described above is not required, the plurality of stereo signals outputted from the second preprocessing unit 310b may be inputted to the second ear boost unit 330b.

The second ear boost unit 330b may adjust the plurality of stereo signals subjected to the reverberation processing to a preset listening volume value, and may adjust the sound source having a low or high volume to a preset listening volume value to output so that the user can hear it.

The second sound source location information provision unit 340b may provide the second sound source location information by using the head-related function (HRTF), and a detailed description will be omitted since similar to the first sound source location information provision unit 340a as described above.

The tracking information processing unit 350b may provide head movement information, and the head movement information (e.g., left and right movements, up and down movements) can be obtained through head movement tracking technology, wherein the head movement tracking technology can extract head position and head orientation by using a head tracker that periodically measures the position and orientation of the listener head in order to calculate each relative location in the spatial representation of the sound source.

Such a head tracker may track and detect the listener's head movement by using sensors such as gyroscopes, acceleration sensors, and magnetometers.

The second sound image localization unit 360b may perform the second sound image localization by reflecting the second sound source location information and head movement information on the plurality of stereo signals adjusted to the preset listening volume value, and may perform the second sound image localization for determining the location of the sound image by linking the first sound source location information provided by using the head-related transfer function (HRTF) with the head movement information (e.g., left and right movements, up and down movements, etc.) tracked and obtained through the head tracker.

The 2-2nd reverberation processing unit 370b may selectively perform reverberation processing on the plurality of stereo signals where the second sound image localization is performed, for a sense of spatiality of the sound source and additional reverberation processing of the sound source may be selectively performed to enable the sound source to have the sense of spatiality in the case of the sound source requiring the sense of additional spatiality.

When the reverberation processing of the 2-2nd reverberation processing unit 370b as described above is not required, the plurality of stereo signals where the second sound image localization is performed through the second sound image localization unit 360b may be outputted to the sound source output processing unit 400.

As described above, the second sound image localization unit 360b may include a second elevation pinna filter unit 361b, a second azimuth pinna filter unit 363b, a second head shadow filter unit 365b, and the like, as shown in FIG. 5.

Herein, the second elevation pinna filter unit 361b may process a pinna effect by the elevation position of the sound image for the plurality of stereo signals, and may process and output the elevation position of the sound image by applying an elevation pinna filter where the pinna effect is applied.

Such a second elevation pinna filter unit 361b may include a 2-1st elevation pinna filter 361b/1 where a left input signal L is inputted and a 2-2nd elevation pinna filter 361b/2 where a right input signal R is inputted, and may process the elevation position of the sound image for each of the left input signal and the right input signal of the stereo signals.

The second azimuth pinna filter 363b may process a pinna effect by a direction angular position of the sound image for the plurality of stereo signals, and may process and output the direction angular effect of the sound image by applying an azimuth pinna filter where the pinna effect is applied.

Such a second azimuth pinna filter unit 363b may include a 2-1st azimuth pinna filter 363b/1 where a left input signal L is inputted and a 2-2nd azimuth pinna filter 363b/2 where a right input signal R is inputted, and may process the direction angular effect of the sound image for each of the left input signal and the right input signal of the stereo signals.

Herein, the left input signal L of the stereo signal may be inputted to a second head shadow filter unit 365b by processing the elevation position and direction angular effect of the sound image through the 2-1st elevation pinna filter 361b/1 and the 2-1st azimuth pinna filter 363b/1, and the right input signal R of the stereo signal may be inputted to the second head shadow filter unit 365b by processing the elevation position and direction angular effect of the sound image through the 2-2nd elevation pinna filter 361b/2 and the 2-2nd azimuth pinna filter 363b/2. Herein, a delay circuit may be provided so that the left input signal L and the right input signal R can be inputted to the second head shadow filter unit 365b at the same time.

The second head shadow filter unit 365b may process an effect by the human head shape on the plurality of stereo signals outputted from the second elevation pinna filter unit 361b and the second azimuth pinna filter unit 363b, and may process and output a difference of the sound image caused by the human head so that sound sources in the left and right directions can be recognized, by applying the head shadow filter developed by modeling a head-related impulse response (HRIR) curve, which is obtained by measuring the difference in distance between ears and the effect by the human head shape according to the direction of sounds by using the head shadow effect.

When the filters provided in the second sound image localization unit 360b as described above are applied, realistic sounds having a sense of distance and direction may be outputted and heard even when using headphones or earphones.

In addition, the second sound image localization unit 360b as described above may process sound image localization in real time to fit the changing location and distance values for each of eight or more multi-channels and multi-objects, by implementing with a IIR (infinite impulse response) filter through lowering the order of each filter to 1st or 2nd order in order to minimize the amount of computation and memory usage so that portable terminals and the like can be applied.

The sound source output processing unit 400 may post-process and output the plurality of stereo signals outputted through the multi-audio rendering unit 300, and may include a volume normalizing unit 410, a downmixing unit 420, an equalizer processing unit 430, and the like as shown in FIG. 6.

Herein, the volume normalizing unit 410 may adjust the volume difference for the plurality of stereo signals outputted through the multi-audio rendering unit 300, and may adjust the volume of each sound source for the plurality of stereo signals outputted through the multi-audio rendering unit 300.

The downmixing unit 420 may downmix the plurality of stereo signals outputted through the volume normalizing unit 410 in response to the number of channels, and may downmix the plurality of stereo signals whose volume of each sound source is adjusted in order to fit the number of channels of the final output device.

The equalizer processing unit 430 may perform equalizer adjustment on the plurality of stereo signals outputted through the downmixing unit 420 to output, and may perform the equalizer adjustment to fit the characteristics of the listener or the final output device to finally output.

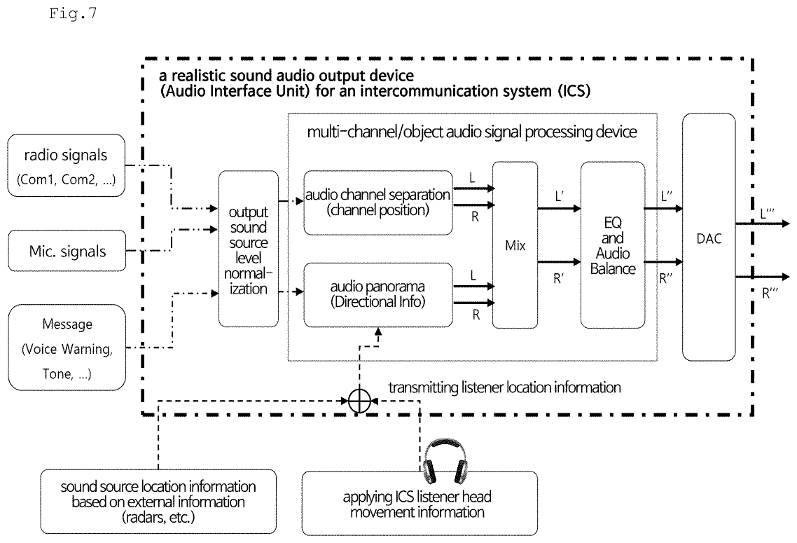

Meanwhile, FIG. 7 is a view showing a system to which a realistic acoustic audio output device for intercommunication according to an exemplary embodiment of the present disclosure is applied, and may illustrate a system to which a realistic acoustic audio output device for intercommunication according to an exemplary embodiment of the present disclosure is applied, wherein when a radio signal, a Mic signal, and a message are inputted to an output sound source level normalization block, and the output sound source level is normalized and inputted to the realistic acoustic audio output device for intercommunication according to an exemplary embodiment of the present disclosure, audio mixing is performed, followed by equalizer and audio balancing (EQ and Audio Balance) processing, and then realistic sounds can be outputted through a DAC, after performing the sound image localization of the sound source where sound source location information according to external information and ICS listener head movement information are applied.

Thus, according to an exemplary embodiment of the present disclosure, a realistic sound can be heard in a stereo listening environment through applying a sense of spatiality to each channel through sound image localization, by reducing ambient noise in a noise reduction unit when a plurality of audio signals are inputted, by outputting a plurality of stereo signals in a multi-sound source determination unit after determining whether a plurality of processed audio signals transmitted are stereo sound sources, by performing a first sound image localization reflecting sound source location information or a second sound image localization reflecting the sound source location information and tracking information with respect to a plurality of outputted stereo signals in a multi-audio rendering unit, and by post-processing and outputting in a sound source output processing unit.

Various exemplary embodiments of the present disclosure may be presented and described in the description above, but the present disclosure may not be necessarily limited thereto, and those skilled in the art to which the present disclosure pertains will easily understand that various substitutions, modifications, and alterations are possible within a scope that does not depart from the technical characteristics of the present disclosure.

### DESCRIPTION OF REFERENCE NUMERALS

100: noise reduction unit
200: multi-sound source determination unit
300: multi-audio rendering unit
300A: audio channel separation rendering unit
300B: audio panorama rendering unit
400: sound source output processing unit

1. A realistic acoustic audio output device for intercommunication, the device comprising:
a noise reduction unit for reducing ambient noise when a plurality of audio signals are inputted;
a multi-sound source determination unit for outputting the plurality of stereo signals after determining whether a plurality of processed audio signals transmitted through the noise reduction unit are stereo sound sources;
a multi-audio rendering unit composed of an audio channel separation rendering unit for performing a first sound image localization reflecting sound source location information with respect to the plurality of stereo signals or an audio panorama rendering unit for performing a second sound image localization reflecting the sound source location information and tracking information; and
a sound source output processing unit for post-processing and outputting the plurality of stereo signals through the multi-audio rendering unit.

2. The device of claim 1, wherein the audio channel separation rendering unit comprises:
a first preprocessing unit for performing preprocessing in order to prevent distortion of a sound source with respect to the plurality of stereo signals;
a 1-1st reverberation processing unit for selectively processing reverberation on the plurality of preprocessed stereo signals for a sense of spatiality of the sound source;
a first ear boost unit for adjusting the plurality of stereo signals subjected to a reverberation processing to a preset listening volume value;
a first sound source location information provision unit for providing a first sound source location information by using a head-related transfer function (HRTF);
a first sound image localization unit for performing the first sound image localization on the plurality of stereo signals adjusted to the preset listening volume value by reflecting the first sound source location information; and
a 1-2nd reverberation processing unit for selectively processing reverberation for the sense of spatiality of the sound source on the plurality of stereo signals on which the first sound image localization is performed.

3. The device of claim 2, wherein the first sound image localization unit comprises:
an elevation pinna filter unit for processing a pinna effect depending on an elevation position of a sound image with respect to the plurality of stereo signals;
an azimuth pinna filter unit for expressing a location depending on a direction angle on a horizontal plane with respect to the plurality of stereo signals; and
a head shadow filter unit for processing an effect depending on a human head shape with respect to the plurality of stereo signals outputted from the elevation pinna filter unit and the azimuth pinna filter unit.

4. The device of claim 1, wherein the audio panorama rendering unit comprises:
a second preprocessing unit for performing preprocessing in order to prevent distortion of a sound source with respect to the plurality of stereo signals;
a 2-1st reverberation processing unit for selectively processing reverberation on the plurality of preprocessed stereo signals for a sense of spatiality of the sound source;
a second ear boost unit for adjusting the plurality of stereo signals subjected to a reverberation processing to a preset listening volume value;
a second sound source location information provision unit for providing a second sound source location information by using a head-related transfer function (HRTF);
a tracking information processing unit for providing head movement information;
a second sound image localization unit for performing the second sound image localization on the plurality of stereo signals adjusted to the preset listening volume value by reflecting the second sound source location information and the head movement information; and
a 2-2nd reverberation processing unit for selectively processing reverberation for the sense of spatiality of the sound source on the plurality of stereo signals on which the second sound image localization is performed.

5. The device of claim 4, wherein the second sound image localization unit comprises:
an elevation pinna filter unit for processing a pinna effect depending on an elevation position of a sound image with respect to the plurality of stereo signals;
an azimuth pinna filter unit for expressing a location depending on a direction angle on a horizontal plane with respect to the plurality of stereo signals; and
a head shadow filter unit for processing an effect depending on a human head shape with respect to the plurality of stereo signals outputted from the elevation pinna filter unit and the azimuth pinna filter unit.

6. The device of claim 3, wherein the sound source output processing unit comprises:
a volume normalizing unit for adjusting a volume difference with respect to the plurality of stereo signals outputted through the multi-audio rendering unit;
a downmixing unit for downmixing the plurality of stereo signals outputted through the volume normalizing unit in response to the number of channels; and
an equalizer processing unit for performing an equalizer adjustment on the plurality of stereo signals outputted through the downmixing unit and outputting the same.

7. The device of claim 5, wherein the sound source output processing unit comprises:
a volume normalizing unit for adjusting a volume difference with respect to the plurality of stereo signals outputted through the multi-audio rendering unit;
a downmixing unit for downmixing the plurality of stereo signals outputted through the volume normalizing unit in response to the number of channels; and
an equalizer processing unit for performing an equalizer adjustment on the plurality of stereo signals outputted through the downmixing unit and outputting the same.
